(19) United States
(12) Patent Application Publication
(10) Pub. No.: US 2009/0085033 A1
(43) Pub. Date: Apr. 2, 2009

(54) THIN FILM TRANSISTOR, PIXEL STRUCTURE AND FABRICATION METHODS THEREOF

(75) Inventors: Ta-Jung Su, Changhua County (TW); Wen-Cheng Lu, Taoyuan County (TW); Meng-Ju Hsieh, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: CHUNGHWA PICTURE TUBES, LTD., Taipei (TW)

(21) Appl. No.: 12/061,657

(22) Filed: Apr. 3, 2008

(30) Foreign Application Priority Data
Sep. 29, 2007 (TW) 96136577

(51) Int. Cl. H01L 29/786; H01L 21/336; H01L 33/00

(52) U.S. Cl. 257/59; 257/60; 438/158; 438/34; 257/E33.053; 257/E29.273; 257/E21.412

(57) ABSTRACT

A thin film transistor including a gate, a gate insulator layer, a doped semiconductor layer, a channel layer, a source, and a drain is provided. The gate is disposed on a substrate, and the gate insulator layer is disposed on the substrate and covers the gate. The doped semiconductor layer is disposed on the gate insulator layer above the gate. Furthermore, the channel layer is disposed on the doped semiconductor layer. The source and the drain are disposed separately on two sides of the channel layer.

### CROSS-REFERENCE TO RELATED APPLICATION

This application claims the priority benefit of Taiwan application serial no. 96136577, filed on Sep. 29, 2007. The entirety the above-mentioned patent application is hereby incorporated by reference herein and made a part of specification.

### BACKGROUND OF THE INVENTION

1. Field of the Invention

The present invention relates to a semiconductor device and a fabricating method thereof. More particularly, the present invention relates to a thin film transistor, a pixel structure, and fabricating methods thereof.

2 Description of Related Art

In recent years, with the progress of semiconductor process technology, the fabrication of thin film transistors becomes easier and faster. Thin film transistors have wide applications, for example, in computer chips, mobile phone chips, or thin film transistor liquid crystal displayers (TFT-LCD). For example, in TFT-LCDs, thin film transistors may be used as switches for charging or discharging.

FIG. 1A is a schematic structural view of a conventional thin film transistor. The conventional thin film transistor 100 includes a glass substrate 110, a gate 120, a gate insulator layer 130, an amorphous silicon layer 140, an N-doped amorphous silicon layer 150, a source 160, and a drain 170. The gate 120 is formed on the glass substrate 110, and is made of a low-resistance material. Further, the gate insulator layer 130 covers the gate 120 and a portion of the glass substrate 110. Additionally, the amorphous silicon layer 140 is formed on the gate insulator layer 130 to provide an electron transport channel. The N-doped amorphous silicon layer 150 (ohmic contact layer) covers a portion of the amorphous silicon layer 140 to reduce the resistance between the source 160 and the amorphous silicon layer 140 and between the drain 170 and the amorphous silicon layer 140. It can be known from FIG. 1A that, both the source 160 and the drain 170 are disposed on the N-doped amorphous silicon layer 150.

When a positive gate voltage Vg is applied to the gate 120 of the thin film transistor 100, an electronic channel is formed in the amorphous silicon layer 140. On the other hand, the data voltage applied to the source 160 flows to the drain 170 through the electronic channel in the form of current, and the current is increased with the rising of the gate voltage Vg. When the voltage is stopped being applied to the gate 120, the electronic channel in the amorphous silicon layer 140 is disappeared. That is to say, the channel between the source 160 and the drain 170 breaks.

FIG. 1B shows an I-V curve of the conventional thin film transistor. Referring to FIG. 1B, it is notable that, when the gate voltage applied to the gate 120 is a negative voltage, the current in the channel is increased with the rising of the negative voltage. For the conventional thin film transistor 100, when the negative voltage is applied to the gate 120, a current flows through the amorphous silicon layer 140 to form a leakage current. As shown in FIG. 1B; when the gate voltage is −10 V, the leakage current between the source 160 and the drain 170 is about 6.00×10⁻¹² mA.

### SUMMARY OF THE INVENTION

Accordingly, the present invention is directed to a thin film transistor, which has a low leakage current in an off state.

The present invention provides a method of fabricating a thin film transistor, so as to fabricate a thin film transistor with good device characteristic.

The present invention provides a pixel structure having the thin film transistor with good device characteristic.

The present invention provides a method of fabricating a pixel structure, which can effectively fabricate the pixel structure.

The present invention provides a thin film transistor, which is adapted to be disposed on a substrate. The thin film transistor of the present invention includes a gate, a gate insulator layer, a doped semiconductor layer, a channel layer, a source, and a drain. The gate is disposed on the substrate, and the gate insulator layer is disposed on the substrate and covers the gate. The doped semiconductor layer is disposed on the gate insulator layer above the gate. Furthermore, the channel layer is disposed on the doped semiconductor layer. Additionally, a source and a drain are disposed separately on two sides of the channel layer.

In an embodiment of the present invention, the doped semiconductor layer includes an N-doped amorphous silicon layer.

In an embodiment of the present invention, the doped semiconductor layer contains a pentavalent element, such as phosphorus, arsenic, or other Group V elements.

In an embodiment of the present invention, the thin film transistor further includes an ohmic contact layer disposed between the source and the channel layer and between the drain and the channel layer.

The present invention provides a method of fabricating a thin film transistor, which includes the following steps. First, a substrate is provided. Next, a gate is formed on the substrate. Then, a gate insulator layer is formed on the substrate and covers the gate. Thereafter, a doped semiconductor layer is formed on the gate insulator layer above the gate. Then, a channel layer is formed on the doped semiconductor layer. After that, a source and a drain are separately formed on two sides of the channel layer.

In an embodiment of the present invention, the material of the doped semiconductor layer includes N-doped amorphous silicon.

In an embodiment of the present invention, the material of the doped semiconductor layer contains a pentavalent element, such as phosphorus, arsenic, or other Group V elements.

In an embodiment of the present invention, an ohmic contact layer can be further formed between the source and the channel layer and between the drain and the channel layer.

The present invention provides a pixel structure, adapted to be disposed on a substrate. The pixel structure of the present invention includes a gate, a gate insulator layer, a doped semiconductor layer, a channel layer, a source, a drain, a passivation layer, and a pixel electrode. The gate is disposed on the substrate, and the gate insulator layer is disposed on the substrate, and covers the gate. Furthermore, the doped semiconductor layer is disposed on the gate insulator layer above the gate, and the channel layer is disposed on the doped semiconductor layer. Additionally, the source and the drain are disposed separately on two sides of the channel layer. The passivation layer at least covers the source and the drain, and the passivation layer has a contact window opening to expose the drain. The pixel electrode is disposed on the passivation layer, and the pixel electrode is electrically connected to the drain through the contact window opening.

The present invention provides a method of fabricating a pixel structure, which includes the following steps. First, a substrate is provided. Next, a gate is formed on the substrate, and a gate insulator layer is formed on the substrate and covers the gate. Then, a doped semiconductor layer is formed on the gate insulator layer above the gate. Thereafter, a channel layer is formed on the doped semiconductor layer. Furthermore, a source and a drain are separately formed on two sides of the channel layer. Then, a passivation layer is formed to cover the source and the drain, and a contact window opening is formed on the passivation layer to expose the drain. After that, a pixel electrode is formed on the passivation layer and electrically connected to the drain through the contact window opening.

As a doped semiconductor layer is disposed below the channel layer of the thin film transistor of the present invention, the leakage current of the thin film transistor in an off state may be significantly reduced. Furthermore, the method of fabricating the thin film transistor of the present invention is compatible with the current processes, so the method of fabricating the thin film transistor of the present invention does not need additional process equipments.

In order to make the aforementioned and other objects, features and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a portion of this specification. The drawings illustrate embodiments of the invention and, together with the description, serve to explain the principles of the invention.

FIG. 1A is a schematic structural view of a conventional thin film transistor.

FIG. 1 B shows an I-V curve of the conventional thin film transistor.

FIGS. 2A to 2E illustrate a method of fabricating a thin film transistor according to a first embodiment of the present invention.

FIG. 3 shows an I-V curve of the thin film transistor according to the first embodiment of the present invention.

FIGS. 4A to 4G illustrate a method of fabricating a pixel structure according to a second embodiment of the present invention.

### DESCRIPTION OF EMBODIMENTS

### The First Embodiment

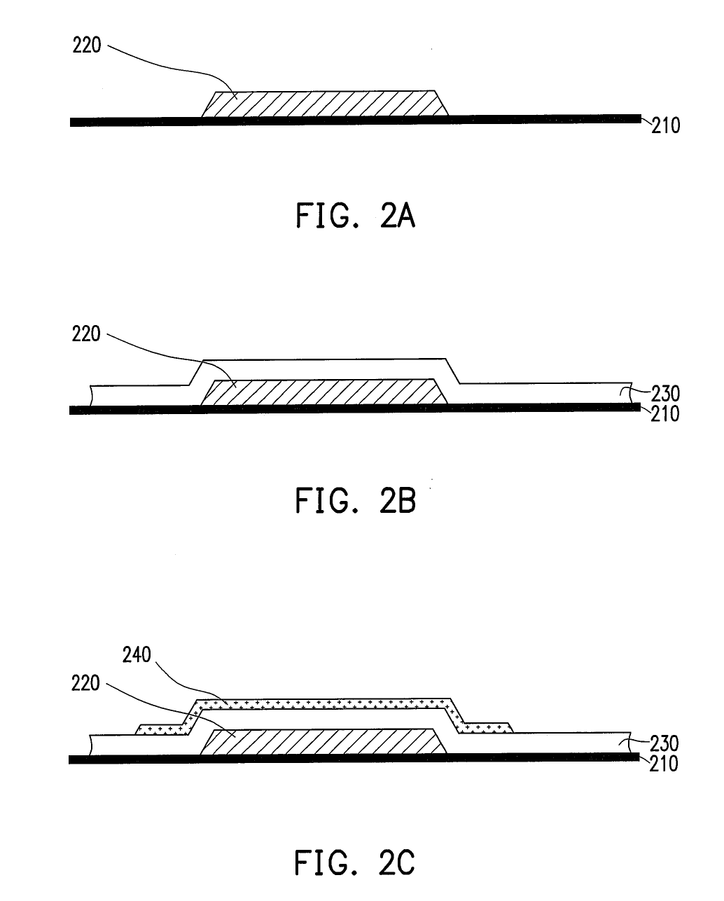

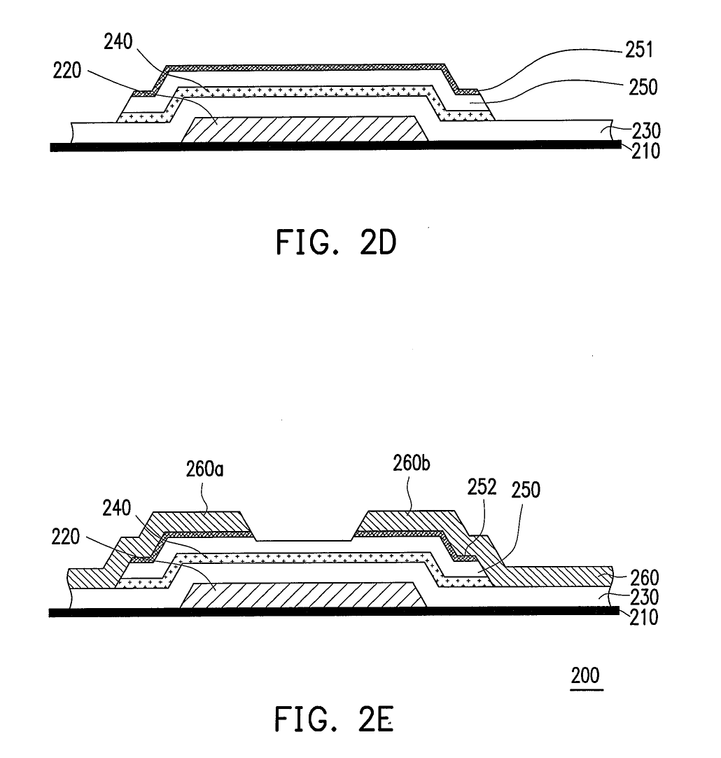

FIGS. 2A to 2E are schematic cross-sectional views of processes of fabricating a thin film transistor according to a first embodiment of the present invention. First, referring to FIG. 2A, a substrate 210 is provided. Next, a gate 220 is formed on the substrate 210. In detail, the gate 220 may be formed by depositing a metal material on the substrate 210 by, for example, physical vapor deposition (PVD), and then patterning the metal material by a mask process.

Next, referring to FIG. 2B, a gate insulator layer 230 is formed on the substrate 210 to cover the gate 220. The material of the gate insulator layer 230 may be silicon nitride or silicon oxide (SiO) formed using tetra-ethyl-ortho-silicate (TEOS) as a reaction gas source.

Then, referring to FIG. 2C, a doped semiconductor layer 240 is formed on the gate insulator layer 230 above the gate 220. In this embodiment of the present invention, the method of forming the doped semiconductor layer 240 may be a chemical vapor deposition process using phosphine (PH₃), silane (SiH₄), or hydrogen gas as the reaction gas source. Particularly, in this embodiment, the material of the doped semiconductor layer 240 contains a dopant of a pentavalent element, so the doped semiconductor layer is, for example, an N-doped amorphous silicon layer, and the pentavalent element is, for example, phosphorus or arsenic. In other embodiment, the doped semiconductor layer may also be a P-doped amorphous silicon layer and is not limited to this.

Thereafter, referring to FIG. 2D, a channel layer 250 is formed on the doped semiconductor layer 240 by, for example, chemical vapor deposition (CVD). In practice, the material of the channel layer 250 includes amorphous silicon. It should be explained that, in order to reduce the contact resistance between the metal material and the semiconductor material (amorphous silicon), a doped semiconductor layer 251 is formed on the channel layer 250, and the material of the doped semiconductor layer 251 is, for example, N-doped amorphous silicon.

Then, referring to FIG. 2E, a source 260a and a drain 260b are separately formed on two sides above the channel layer 250. In detail, the method of forming the source 260a and the drain 260b includes, for example, the following steps. First, a metal material layer 260 is formed on the doped semiconductor layer 251 by physical vapor deposition. Next, a patterning process is performed on the metal material layer 260 and the doped semiconductor layer 251. The metal material layer 260 may be patterned to form the source 260a and the drain 260b, and the doped semiconductor layer 251 may be patterned to form an ohmic contact layer 252. Till now, the thin film transistor 200 of the present invention is substantially fabricated.

As shown in FIG. 2E, the thin film transistor 200 of this embodiment is a bottom gate structure, and the material of the gate 220 is a low-resistance material, for example, aluminum, gold, copper, molybdenum, chromium, titanium, aluminum alloy, or molybdenum alloy. Additionally, the material of the source 260a and the drain 260b is a low-resistance material, for example, aluminum, molybdenum, titanium, gold, copper, chromium, silver, or tantalum. In detail, the thin film transistor 200 may be turned on or off by controlling the voltage applied to the gate 220.

It is notable that, the doped semiconductor layer 240 may be disposed between the gate insulator layer 230 and the channel layer 250. As the doped semiconductor layer 240 contains a Group V element (such as phosphorus or arsenic), the doped semiconductor layer 240 can provide additional electrons to neutralize the excess holes generated by the channel layer 250 due to the negative voltage applied to the gate 220, thereby achieving the purpose of inhibiting the leakage current.

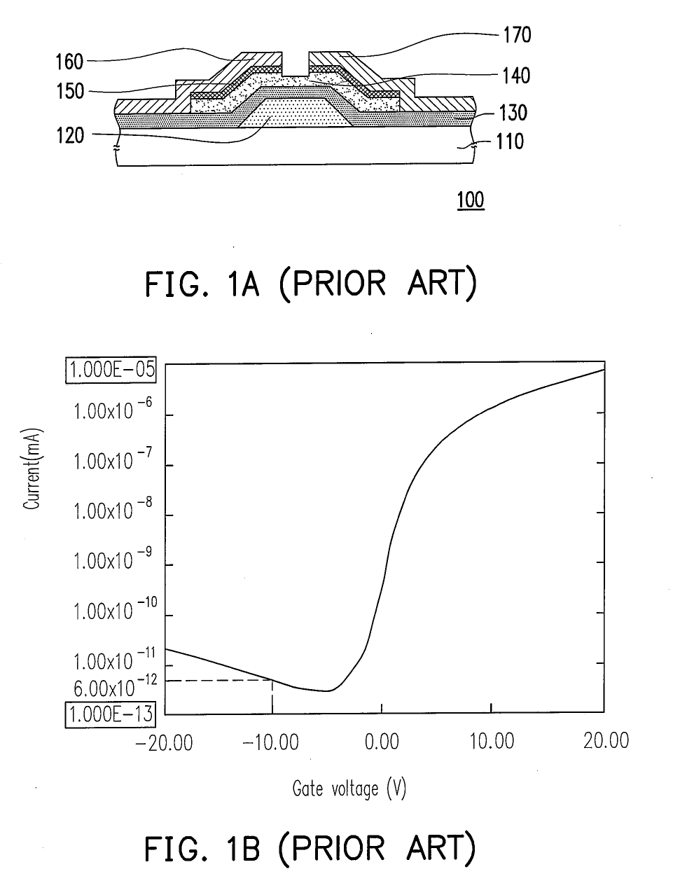

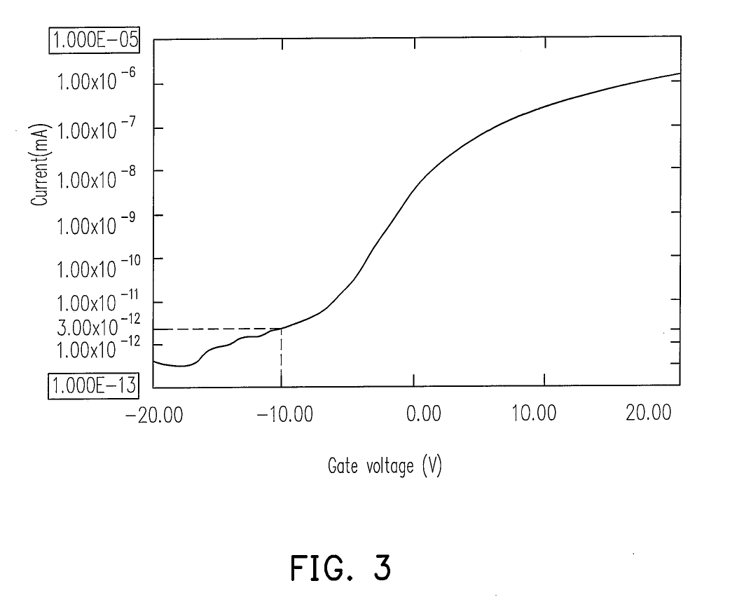

FIG. 3 shows an I-V curve of the thin film transistor according to the first embodiment of the present invention. Referring to FIG. 3, when the gate voltage Vg of the thin film transistor of the present invention is negative, the current does not increase with the positive voltage. When the gate voltage Vg is −10 V, the current is about 3.00×10⁻¹² A. Compared with FIG. 1B, when the gate voltage Vg of the conventional thin film transistor 100 is −10 V, the current is up to about 6.00×10⁻¹² A. It can be seen that, the thin film transistor 200 of the present invention has a significant inhibiting effect on the generation of leakage current when the gate 220 is subjected to a negative voltage. Therefore, the thin film transistor 200 of the present invention has good device characteristic.

### The Second Embodiment

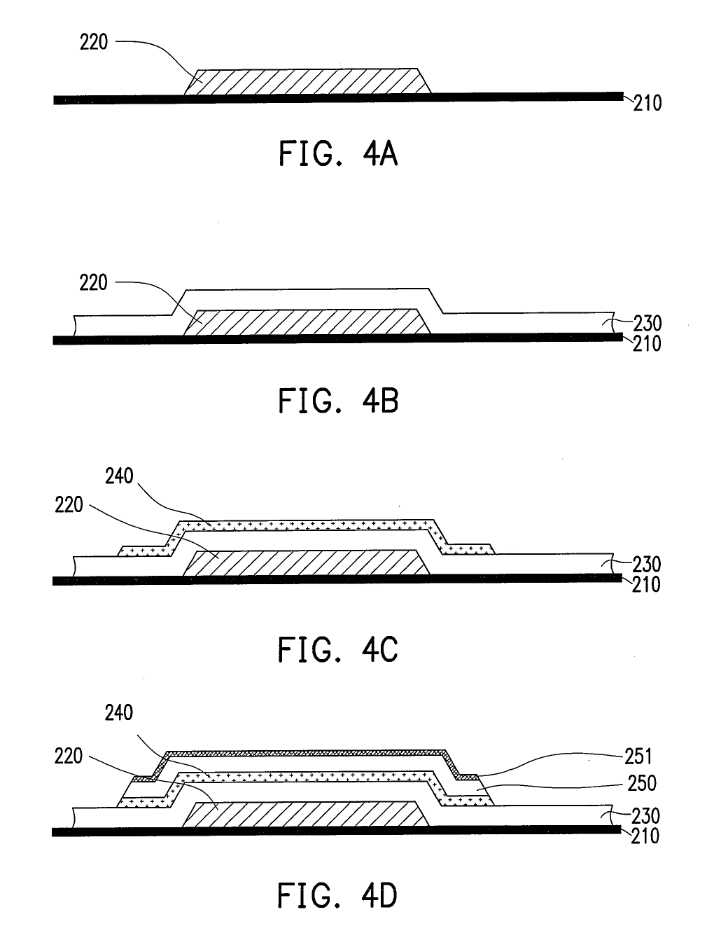

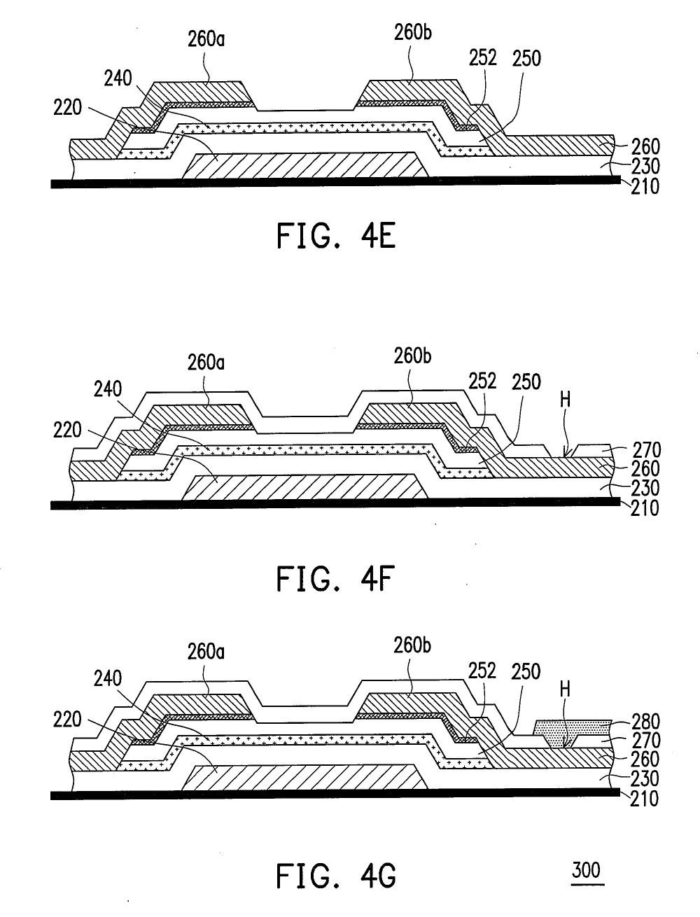

FIGS. 4A to 4G illustrate a method of fabricating a pixel structure according to a second embodiment of the present invention. A gate 220, a gate insulator layer 230, a doped semiconductor layer 240, a channel layer 250, an ohmic contact layer 252, a source 260a, and a drain 260b of a pixel structure 300 are similar to those of the thin film transistor 200 of the first embodiment, and the fabrication processes are shown in FIGS. 4A to 4E and will not be repeated herein.

Directly referring to FIG. 4F, in this embodiment, after the source 260a and the drain 260b are formed, a passivation layer 270 may be further formed to cover the source 260a and the drain 260b. The passivation layer 270 has a contact window opening H to expose the drain 260b. In detail, the material of the passivation layer 270 is, for example, silicon nitride, silicon oxide, silicon oxynitride, silicon carbide, organic silicon, an organic material, or a combination thereof.

Then, referring to FIG. 4G, a pixel electrode 280 is formed on the passivation layer 270 and electrically connected to the drain 260b through the contact window opening H. In practice, the method of forming the pixel electrode 280 is, for example, a sputtering process of physical vapor deposition. Generally speaking, the material of the pixel electrode 280 is, for example, indium-tin-oxide, indium-zinc-oxide, aluminum-zinc-oxide, zinc oxide, indium oxide, or other transparent conductive materials. Till now, the pixel structure 300 of the present invention is substantially fabricated.

As the doped semiconductor layer 240 is disposed below the channel layer 250, when the gate 220 is subjected to a negative voltage, the leakage current at the channel layer 250 can be effectively inhibited. That is to say, the pixel electrode 280 can be accurately charged and discharged, thus achieving a good display quality.

In view of above, as a doped semiconductor layer is disposed below the channel layer of the thin film transistor of the present invention, the leakage current of the thin film transistor in an off state can be effectively inhibited. The thin film transistor of the present invention has good device characteristic, and the pixel structure of the present invention can be charged and discharged more effectively. Furthermore, the method of fabricating the thin film transistor of the present invention is compatible with the current processes, the method of fabricating the thin film transistor of the present invention does not need additional process equipments.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A thin film transistor, adapted to be disposed on a substrate, comprising:
a gate, disposed on the substrate;
a gate insulator layer, disposed on the substrate, and covering the gate;
a doped semiconductor layer, disposed on the gate insulator layer above the gate;
a channel layer, disposed on the doped semiconductor layer; and
a source and a drain, disposed separately on two sides of the channel layer.

2. The thin film transistor as claimed in claim 1, wherein the doped semiconductor layer comprises an N-doped amorphous silicon layer.

3. The thin film transistor as claimed in claim 1, wherein the doped semiconductor layer comprises a pentavalent element.

4. The thin film transistor as claimed in claim 3, wherein the doped semiconductor layer comprises phosphorus.

5. The thin film transistor as claimed in claim 3, wherein the doped semiconductor layer comprises arsenic.

6. The thin film transistor as claimed in claim 1, further comprising an ohmic contact layer disposed between the source and the channel layer and between the drain and the channel layer.

7. A method of fabricating a thin film transistor, comprising:
providing a substrate;
forming a gate on the substrate;
forming a gate insulator layer on the substrate, and covering the gate;
forming a doped semiconductor layer on the gate insulator layer above the gate;
forming a channel layer on the doped semiconductor layer; and
forming a source and a drain separately on two sides of the channel layer.

8. The method of fabricating a thin film transistor as claimed in claim 7, wherein the material for forming the doped semiconductor layer comprises N-doped amorphous: silicon.

9. The method of fabricating a thin film transistor as claimed in claim 7, wherein the material of the doped semiconductor layer comprises a pentavalent element.

10. The method of fabricating a thin film transistor as claimed in claim 9, wherein the material of the doped semiconductor layer comprises phosphorus.

11. The method of fabricating a thin film transistor as claimed in claim 9, wherein the material of the doped semiconductor layer comprises arsenic.

12. The method of fabricating a thin film transistor as claimed in claim 7, further comprising forming an ohmic contact layer between the source and the channel layer and between the drain and the channel layer.

13. A pixel structure, adapted to be disposed on a substrate, comprising:
a gate, disposed on the substrate;
a gate insulator layer, disposed on the substrate, and covering the gate;
a doped semiconductor layer, disposed on the gate insulator layer above the gate;
a channel layer, disposed on the doped semiconductor layer;
a source and a drain, separately disposed on two sides of the channel layer;
a passivation layer, at least covering the source and the drain, and having a contact window opening to expose the drain; and
a pixel electrode, disposed on the passivation layer, and electrically connected to the drain through the contact window opening.

14. The pixel structure as claimed in claim 13, wherein the material of the doped semiconductor layer comprises N-doped amorphous silicon.

15. The pixel structure as claimed in claim 14, wherein the material of the doped semiconductor layer comprises a pentavalent element.

16. The pixel structure as claimed in claim 15, wherein the material of the doped semiconductor layer comprises phosphorus.

17. The pixel structure as claimed in claim 15, wherein the material of the doped semiconductor layer comprises arsenic.

18. The pixel structure as claimed in claim 7, further comprising an ohmic contact layer disposed between the source and the channel layer and between the drain and the channel layer.

19. A method of fabricating a pixel structure, comprising:
providing a substrate;
forming a gate on the substrate;
forming a gate insulator layer on the substrate, and covering the gate;
forming a doped semiconductor layer on the gate insulator layer above the gate;
forming a channel layer on the doped semiconductor layer;
forming a source and a drain separately on two sides of the channel layer;
forming a passivation layer at least covering the source and the drain, and forming a contact window opening on the passivation layer to expose the drain; and
forming a pixel electrode on the passivation layer, wherein the pixel electrode is electrically connected to the drain through the contact window opening.
